(19) United States
(12) Patent Application Publication
(10) Pub. No.: US 2026/0023916 A1
(43) Pub. Date: Jan. 22, 2026

(54) METHOD FOR RE-TRAINING A MACHINE LEARNING MODEL FOR DEFECT DETECTION IN AN IMAGE OF A PHOTOLITHOGRAPHY MASK

(71) Applicant: Carl Zeiss SMT GmbH, Oberkochen (DE)

(72) Inventors: Bjoern Froehlich, Jena (DE); Alexander Freytag, Erfurt (DE); Bjoern Barz, Jena (DE); Bjoern Brauer, Magstadt (DE); Xuan Truong Nguyen, Berlin (DE)

(21) Appl. No.: 19/262,445

(22) Filed: Jul. 8, 2025

(30) Foreign Application Priority Data
Jul. 22, 2024 (DE) 102024120809.0

(51) Int. Cl. G06F 30/398; G06N 20/00

(52) U.S. Cl. CPC G06F 30/398; G06N 20/00

(57) ABSTRACT

The invention relates to a method for re-training a pre-trained machine learning model for defect detection in an image of a photolithography mask, the method comprising: acquiring adjustment images of one or more photolithography masks using an inspection system; adjusting at least one parameter of a simulation of the inspection system using the adjustment images; generating training images of one or more photolithography masks using the adjusted simulation of the inspection system; re-training the machine learning model for defect detection using the generated training images; and applying the re-trained machine learning model for defect detection to an image of a photolithography mask acquired by the inspection system.

### CROSS-REFERENCE TO RELATED APPLICATION

This application claims benefit of the German patent application No. 102024120809.0, filed on Jul. 22, 2024, which is hereby incorporated by reference in its entirety.

### TECHNICAL FIELD

The invention relates to methods and systems for quality control and quality assurance in photolithography masks, more specifically to a method for re-training a machine learning model and a corresponding method and inspection system for defect detection in an image of a photolithography mask. The methods and systems can be utilized for quantitative metrology, process monitoring, defect detection and defect review in photolithography masks.

### BACKGROUND

Semiconductor manufacturing involves precise manipulation, e.g., etching, of materials such as silicon or oxide at very fine scales in the range of nm. Therefore, a quality management process comprising quality assurance and quality control is important for ensuring high quality standards of the manufactured wafers. Quality assurance refers to a set of activities for ensuring high-quality products by preventing any defects that may occur in the development process. Quality control refers to a system of inspecting the final quality of the product. Quality control is part of the quality assurance process.

A wafer made of a thin slice of silicon serves as the substrate for microelectronic devices containing semiconductor structures built in and upon the wafer. The semiconductor structures are constructed layer by layer using repeated processing steps that involve repeated chemical, mechanical, thermal and optical processes. Dimensions, shapes and placements of the semiconductor structures and patterns are subject to several influences. One of the most crucial steps is the photolithography process.

Photolithography is a process used to produce patterns on the substrate. The patterns to be printed on the surface of the substrate are generated by computer-aided-design (CAD). From the design, for each layer a photolithography mask is generated, which contains a magnified image of the computer-generated pattern to be etched into the substrate. The photolithography mask can be further adapted, e.g., by use of optical proximity correction techniques. During the printing process an illuminated image projected from the photolithography mask is focused onto a photoresist thin film formed on the substrate. A semiconductor chip powering mobile phones or tablets comprises, for example, approximately between 80 and 120 patterned layers.

Due to the growing integration density in the semiconductor industry, photolithography masks have to image increasingly smaller structures onto wafers. The aspect ratio and the number of layers of integrated circuits constantly increases and the structures are growing into 3^{rd} (vertical) dimension. The current height of the memory stacks is exceeding a dozen of microns. In contrast, the feature size is becoming smaller. The minimum feature size or critical dimension is below 10 nm, for example 7 nm or 5 nm, and is approaching feature sizes below 3 nm in near future. While the complexity and dimensions of the semiconductor structures are growing into the 3^{rd} dimension, the lateral dimensions of integrated semiconductor structures are becoming smaller. Producing the small structure dimensions imaged onto the wafer requires photolithographic masks or templates for nanoimprint photolithography with ever smaller structures or pattern elements. The production process of photolithographic masks and templates for nanoimprint photolithography is, therefore, becoming increasingly more complex and, as a result, more time-consuming and ultimately also more expensive. With the advent of EUV photolithography scanners, the nature of masks changed from transmission-based to reflection-based patterning.

On account of the tiny structure sizes of the pattern elements of photolithographic masks or templates, it is not possible to exclude errors during mask or template production. The resulting defects can, for example, arise from degeneration of photolithography masks or particle contamination. Of the various defects occurring during semiconductor structure manufacturing, photolithography related defects make up nearly half of the number of defects. Hence, in semiconductor process control, photolithography mask inspection, review, and metrology play a crucial role to monitor systematic defects. Defects detected during quality assurance processes can be used for root cause analysis, for example, to modify or repair the photolithography mask. The defects can also serve as feedback to improve the process parameters of the manufacturing process, e.g., exposure time, focus variation, etc.

Each defect in the photolithography mask can lead to unwanted behavior of the produced wafer, or a wafer can be significantly damaged. Therefore, each defect must be found and repaired if possible and necessary. Reliable and fast defect detection methods are, therefore, important for photolithography masks.

In order to analyze large amounts of data requiring large amounts of measurements to be taken, machine learning methods can be used. Machine learning is a field of artificial intelligence. Machine learning methods generally build a parametric machine learning model based on training data consisting of a large number of samples. After training, the method is able to generalize the knowledge gained from the training data to new previously unencountered samples, thereby making predictions for new data. There are many machine learning methods, e.g., linear regression, k-means, support vector machines, decision trees, random forests, neural networks or deep learning approaches.

Deep learning is a class of machine learning that uses artificial neural networks with numerous hidden layers between the input layer and the output layer. Due to this complex internal structure the networks are able to progressively extract higher-level features from the raw input data. Each level learns to transform its input data into a slightly more abstract and composite representation, thus deriving low and high level knowledge from the training data. The hidden layers can have differing sizes and tasks such as convolutional or pooling layers.

Yet, defect detection methods suffer from the problem of changing conditions. For example, the optical properties of photolithography masks change during their use in photolithography processes, e.g., by EUV exposure tools. In addition, different photolithography masks can vary not only in their design but also in their material. Therefore, it is important to adapt existing defect detection methods to altering conditions, e.g., to a different inspection system and/or to a different photolithography mask and/or to modified conditions in the inspection system and/or to modifications of the optical properties of the photolithography mask, etc. For example, reference images used in defect detection methods must be adapted to changing conditions to prevent high numbers of false positive defect detections, images from different machines or even different types of machines can vary significantly (e.g., in contrast or appearance), e.g., due to different materials or due to changing optical properties of the photolithography mask. All these scenarios require a fast adaptation of the defect detection method to changing conditions. Yet, machine learning models require large amounts of training data that is usually not available in these cases.

To alleviate this problem, domain adaptation methods have been proposed in the literature. Domain adaptation methods try to directly adapt the model to the changing conditions, or to adapt the training data of the model to the changing conditions. However, due to the lack of knowledge about the image formation process, many training images of the new domain are still required for training—otherwise the adaptation cannot be robustly estimated.

Therefore, it is an aspect of the invention to adapt a trained machine learning model for defect detection in an image of a photolithography mask to modified conditions. In particular, it is an aspect of the invention to adapt the machine learning model requiring only little acquired training data reflecting the modified conditions, with little user effort and requiring little time for image acquisition. Furthermore, it is an aspect to increase the accuracy of the predictions of the re-trained machine learning model.

The aspects are achieved by the invention specified in the independent claims. Advantageous embodiments and further developments of the invention are specified in the dependent claims.

### SUMMARY

Embodiments of the invention concern methods and systems for re-training pre-trained machine learning models for defect detection in images of photolithography masks.

An embodiment of the invention involves a method for re-training a pre-trained machine learning model for defect detection in an image of a photolithography mask, the method comprising: a. acquiring adjustment images of one or more photolithography masks using an inspection system, wherein the inspection system is configured for acquiring images of photolithography masks; b. adjusting at least one parameter of a simulation of the inspection system using the adjustment images; c. generating training images of one or more photolithography masks using the adjusted simulation of the inspection system; and d. re-training the machine learning model for defect detection using the generated training images, for use of the re-trained machine learning model for defect detection in an image of a photolithography mask acquired by the inspection system.

An embodiment of the invention involves a method for defect detection in an image of a photolithography mask using a pre-trained machine learning model, the method comprising: a. acquiring adjustment images of one or more photolithography masks using an inspection system, wherein the inspection system is configured for acquiring images of photolithography masks; b. adjusting at least one parameter of a simulation of the inspection system using the adjustment images; c. generating training images of one or more photolithography masks using the adjusted simulation of the inspection system; d. re-training the machine learning model for defect detection using the generated training images; and e. applying the re-trained machine learning model for defect detection to an image of a photolithography mask acquired by the inspection system.

By using a simulation of the inspection system, the number of required training images of the new domain is low in contrast to domain adaptation methods, since only a few parameters of the simulation require adaptation. This is due to the prior knowledge of the image formation process already contained in the simulation of the inspection system. The adapted simulation of the inspection system can then be used to automatically generate huge amounts of training images to train the defect detection algorithm without having to acquire these amounts of training images.

The at least one parameter of the inspection system is adjusted using adjustment images. To this end, only a small number of adjustment images is required to adjust the simulation of the inspection system. For example, the number of adjustment images is less than 1% of the number of pre-training images used for pre-training the machine learning model, preferably less than 0.1%, more preferably less than 0.01%, most preferably less than 0.001%. After adjusting the simulation of the inspection system to the adjustment images, a huge number of training images can be simulated that are very similar to acquired images of the inspection system. Thus, large numbers of training images can be generated automatically at a low user effort requiring only very few actually acquired images on the inspection system. This procedure allows, for example, to develop a trained machine learning inspection system at a first site that is adapted to different conditions at a second site. Instead of re-training the inspection system at the second site only based on acquired training images from the second site, which is often not possible due to the limited amount of available training images there, the parameters of the simulation of the inspection system only has to be adjusted using very few adjustment images. Then the simulation can be used to generate realistic training images for re-training the machine learning model in the inspection system at the second site. In this way, re-training of the machine learning model becomes feasible in case of modified conditions if only few acquired training images (here adjustment images) are available. At the same time, the user effort for adjusting the machine learning model to the new conditions, e.g., at the second site, is minimized. Furthermore, the time required for adjusting the machine learning model of the inspection system to the new conditions is strongly reduced using the adjusted simulation of the inspection system. In addition, the time for acquiring the required training images is reduced. Finally, the energy consumption of the inspection system, abrasion and wear of the inspection system and of the one or more photolithography masks are reduced.

The term “inspection system” refers to a system that is configured to inspect photolithography masks by taking an image of the photolithography mask and detecting defects in the image. An inspection system can, for example, be a review system or a repair system.

The photolithography mask may have an aspect ratio of between 1:1 and 1:4, preferably between 1:1 and 1:2, most preferably of 1:1 or 1:2. The photolithography mask may have a nearly rectangular shape. The photolithography mask may be preferably 5 to 7 inches long and wide, most preferably 6 inches long and wide. Alternatively, the photolithography mask may be 5 to 7 inches long and 10 to 14 inches wide, preferably 6 inches long and 12 inches wide.

An image of a photolithography mask can refer to various kinds of images of the photolithography mask, e.g., two-dimensional or volumetric three-dimensional images that can, for example, be processed slice by slice. An image can be acquired using an inspection system, or it can be simulated, e.g., from a design of the photolithography mask. Images can be of various modalities, e.g., structured electron microscopy (SEM) images, aerial images, optical images, x-ray images, computer tomography (CT) images, focused-io beam (FIB) images, atomic force microscopy (AFM) images, ultrasound images or multimodal images, e.g., acquired using a combination of x-ray imaging and SEM. An image of a photolithography mask can image a complete photolithography mask or one or more subsections thereof. Preferably, an image of a photolithography mask refers to an aerial image thereof.

A training image, a pre-training image and an adjustment image each comprises at least an image of a photolithography mask. It can further comprise defect annotations or a design of the photolithography mask.

The term “defect” refers to a localized deviation of an integrated circuit pattern from an a priori defined norm of the integrated circuit pattern. For instance, a defect of an integrated circuit pattern, e.g., of a semiconductor structure, can result in malfunctioning of an associated semiconductor device. Depending on the detected defect, for example, the photolithography process can be improved, or photolithography masks or wafers can be repaired or discarded. The norm of the structure or pattern can be defined by one or more corresponding reference photolithography masks or reference datasets, e.g., by design datasets, simulated datasets or acquired defect-free datasets.

A machine learning model for defect detection can perform various tasks such as defect detection (presence or absence of a defect), defect localization (locating a defect), defect segmentation (computing the area, volume or outline of a defect), defect classification (assigning a defect class to a defect), etc. The machine learning model can be a supervised model, an unsupervised model or a semi-supervised model. The machine learning model can use reference datasets, i.e., predominantly defect-free acquired or simulated images, for detecting defects, e.g., a die-to-die model, or it can be a reference-free machine learning model, e.g., a single-die model, that detects defects by detecting deviations from the norm, e.g., from prior knowledge or from knowledge derived from the die itself. A pre-trained machine learning model refers to a machine learning model that has been trained at least once before, i.e., a machine learning model whose parameters have been adapted at least once using training images. Re-training a machine learning model refers to a training of a pre-trained machine learning model, i.e., to a subsequent adaptation of the parameters of the model using further training images.

A simulation of the inspection system refers to a parametric model of the inspection system that simulates the image acquisition process of the inspection system. The simulation of the inspection system can be used to generate simulated images of the photolithography mask. The parameters of the parametric model of the inspection system, i.e., the simulation parameters, can be adapted, e.g., using the adjustment images, to simulate a specific inspection system or specific conditions of the inspection system or of the photolithography mask. The simulation parameters can, for example, comprise
image properties such as an image intensity, an image contrast, a noise level, image distortions, a maximum illumination difference, a maximum focus drift, a maximum misalignment,
defect information,
machine settings such as a light source intensity, light source parameters,
photolithography mask properties such as a layer thickness of the photolithography mask, layer materials of the photolithography mask,
design modification parameters such as line edge roughness, CD variations, pattern thickness, optical proximity correction (OPC) structures,
parameters of a machine learning model, etc.

An aerial image indicates the radiation intensity distribution of a photolithography system in a wafer plane for a given photolithography mask. The aerial image, thus, simulates the structures on the surface of a wafer when printing the wafer using the photolithography mask in the photolithography system. A wafer plane refers to a plane within the resist on top of the wafer in the photolithography system. An aerial image can be generated by applying an aerial image measurement system or metrology system to a photolithography mask. An aerial image can be simulated using a design of a photolithography mask and an aerial image simulation method.

An aerial image can refer to the aerial image of a complete photolithography mask, or it can refer to the aerial image of a section of the photolithography mask. A design can refer to the design of a complete photolithography mask, or it can refer to the design of a section of the photolithography mask.

In case of aerial images, the simulation of the inspection system can simulate the generation of an aerial image of a photolithography mask from a design of the photolithography mask. The simulation can use physics-based models, e.g., physical models of the photolithography mask and/or of the propagation of electromagnetic waves through the photolithography mask. The simulation can also use non-physics-based models, e.g., machine learning models that are trained to generate aerial images from designs using training data. Hybrid methods that use physical models and machine learning models can also be used to simulate aerial images.

In an example, the method further comprises, before step a., pre-training the machine learning model using pre-training images that comprise at least one simulated image generated using the simulation of the inspection system. The simulation of the inspection system can, for example, be used with initial simulation parameters. In this way, the same simulation of the inspection system can be used to generate the pre-training images for the pre-training as is used in step c., thereby strongly reducing the user effort for providing the required pre-training images, reducing the time for acquiring the pre-training images, reducing the energy consumption of the inspection system, and reducing abrasion and wear of the inspection system and of the photolithography mask, etc.

Additionally or alternatively, the method can further comprise, before step a., pre-training the machine learning model using pre-training images that comprise at least one image acquired by an inspection system. In this way, more realistic training images are used for pre-training yielding a higher accuracy of the predictions of the machine learning model.

In a preferred example, at least some training images comprise defect annotations. Defect annotations can, for example, be given by a yes/no indication, by bounding boxes of any shape and size encompassing the defect, by a pixelwise or voxelwise segmentation of the defect, by a description, by one or more items of a defect list, etc. The defect annotations can be used for a supervised training of the machine learning model, thereby improving the accuracy of the detected defects. Even if only few defect annotations are available, these can still be used to improve on the results of an unsupervised training of the machine learning model.

According to an aspect of the invention, the simulation of the inspection system comprises simulating the image acquisition process for a photolithography mask, for example by using a design of the photolithography mask. In this way, highly accurate simulations of images can be generated, e.g., from the design of the photolithography mask.

In an example, the generated training images for training the machine learning model for defect detection comprise simulated images of defective designs, i.e., of designs containing one or more defects, and corresponding defect annotations. The simulated images of the defective designs are obtained by applying the simulation of the inspection system to the defective designs. Defective designs can, for example, be obtained by modifying defect-free designs. The modifications correspond to atypical design structures, i.e., simulated defects. In this way, the simulated defects can be controlled in their location, size, strength, type, frequency, etc. Using the simulated images of the defective designs and corresponding defect annotations the machine learning model for defect detection can be trained in a supervised way yielding defect detections of high accuracy. Optionally, the defect-free design corresponding to the defective design or a simulated image of the defect-free design can be used as an additional input to the machine learning model for defect detection.

According to an example, adjusting the at least one parameter of the simulation of the inspection system in step b. comprises solving an optimization problem. In this way, the accuracy of the adjusted parameters can be improved.

An optimization problem comprises an objective function that is to be maximized or minimized. The optimization problem can also comprise constraints. Solving the optimization problem means applying some kind of mathematical procedure to compute a point with an objective function value that is better than the objective function values for multiple other points. Solving the optimization problem can, for example, mean computing the global optimum or a local optimum of the objective function. The mathematical procedure can comprise computing an analytical solution or applying an iterative method such as gradient descent, a Simplex method, a variational approach, a combinatorial optimization approach, etc.

According to an aspect of the example, for at least one adjustment image a design of the corresponding photolithography mask is available, the simulation of the inspection system simulates the image acquisition process for a photolithography mask using a design of the photolithography mask, and solving the optimization problem comprises minimizing a deviation of one or more adjustment images from the simulated images of the corresponding designs. Thus, the accuracy of the adjusted one or more parameters can be improved.

According to another aspect of the example, solving the optimization problem comprises maximizing the similarity of the distribution of adjustment images and a distribution of simulated images obtained using the simulation of the inspection system. Thus, the accuracy of the adjusted one or more parameters can be improved.

According to another aspect of the example, gradients of the simulation of the inspection system with respect to the at least one parameter are derived, and solving the optimization problem comprises using a gradient descent approach using the derived gradients. Thus, the accuracy of the adjusted one or more parameters can be improved.

In an example, prior knowledge is used for adjusting the at least one parameter of the simulation of the inspection system in step b. Prior knowledge can, for example, comprise known parameters, e.g., a mask thickness or an illumination setting parameter, parameter ranges, or parameter distributions, etc. Such prior knowledge can be used to simplify the optimization problem allowing to obtain solutions at lower computation times, or to improve the solution of the optimization problem to increase the accuracy of the adjusted at least one parameter.

According to an example, the majority of adjustment images differ from pre-training images used for pre-training the machine learning model in at least one aspect from the group comprising the inspection system, the image acquisition time period, the photolithography mask. At least some of the pre-training images used for pre-training the machine learning model can be acquired using an inspection system or they can be simulated using a simulation of an inspection system. Differences can, for example, lie in the type of inspection system, in the instance of an inspection system, in parameters of the inspection system, in the acquisition time period, in the design, material or instance of the photolithography mask, etc. In this way, the pre-trained machine learning model can be adapted to modified conditions.

In an example, the pre-training of the machine learning model is carried out on a first computer system and at least step d. is carried out on a second computer system. In this way, the machine learning model can be adapted to modified conditions between the first computer system and the second computer system. The computer systems can, for example, be located in different locations, or they can have different properties, e.g., a different hardware configuration, different confidentiality standards, different computation time requirements, etc. The first and second computer system can also belong to different inspection systems. In this case, the machine learning model can be adapted to modified conditions between the inspection systems.

According to an aspect of the invention, steps a. to d. are iterated. In this way, a re-trained machine learning model can be re-trained again to adapt it to further modified conditions, e.g., when loading a different photolithography mask into an inspection system.

According to an example, the simulation of the inspection system comprises a physical simulation of the propagation of electromagnetic waves within a photolithography mask, e.g., using rigorous simulations or Kirchhoff's method or further simulation techniques. In this way, the image acquisition process can be simulated with high accuracy or at low computation times, thereby improving the accuracy of the simulation of the inspection system or the computation time.

Additionally or alternatively, the simulation of the inspection system comprises the application of a trained machine learning model. In this way, the accuracy and/or the computation time of the simulation of the inspection system can be improved.

An inspection system for detecting defects in an image of a photolithography mask according to a third embodiment of the invention comprises: an image acquisition unit configured to acquire images of photolithography masks; and a data analysis device comprising at least one memory and at least one processor configured to perform the steps of a method for detecting defects in an image of a photolithography mask according to an embodiment of the invention.

A system for re-training a machine learning model for defect detection in an image of a photolithography mask according to a fourth embodiment of the invention comprises: an image acquisition unit configured to acquire images of photolithography masks; and a data analysis device comprising at least one memory and at least one processor configured to perform the steps of a method for re-training a machine learning model for defect detection in an image of a photolithography mask according to an embodiment of the invention.

The invention described by embodiments, examples and aspects is not limited to the embodiments, examples and aspects, but can be implemented by those skilled in the art by various combinations or modifications thereof.

### BRIEF DESCRIPTION OF DRAWINGS

FIG. 1 illustrates an exemplary transmission-based photolithography system, e.g., a deep ultraviolet (DUV) photolithography system;

FIG. 2 illustrates an exemplary reflection-based photolithography system, e.g., an extreme ultraviolet (EUV) photolithography system;

FIG. 3 shows an example of an imaging dataset of an object comprising integrated circuit patterns in the form of a photolithography mask comprising a defect;

FIG. 4 shows an example of a flowchart illustrating the steps of a method according to an embodiment of the invention;

FIG. 5 illustrates an example of the application of a trained machine learning model for defect detection;

FIG. 6 illustrates an example of the training of a machine learning model that simulates the image acquisition process in an inspection system;

FIGS. 7A-7C illustrate an example of the method for re-training a machine learning model for defect detection according to an embodiment of the invention; and

FIG. 8 illustrates an example of an inspection system for detecting defects in a photolithography mask according to a third embodiment of the invention.

### DETAILED DESCRIPTION

In the following, advantageous exemplary embodiments of the invention are described and schematically shown in the figures. Throughout the figures and the description, same reference numbers are used to describe same features or components. Dashed lines indicate optional features.

The methods and systems herein can be used with a variety of photolithography systems, e.g., transmission-based photolithography systems 10 or reflection-based photolithography systems 10′.

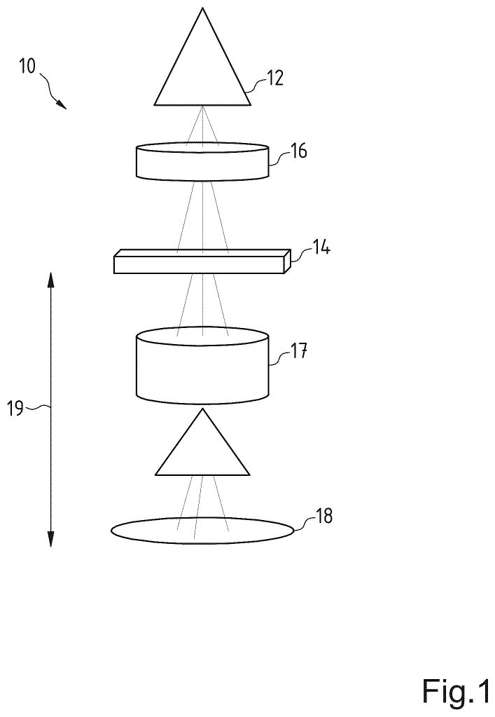

FIG. 1 illustrates an exemplary transmission-based photolithography system 10, e.g., a DUV photolithography system. Major components are a radiation source 12, which may be a deep-ultraviolet (DUV) excimer laser source, imaging optics which, for example, define the partial coherence and which may include optics that shape radiation from the radiation source 12, a photolithography mask 14, illumination optics 16 that illuminate the photolithography mask 14 and projection optics 17 that project an image of the photolithography mask model 92, e.g., the design pattern, onto a wafer plane 18. An adjustable filter or aperture at the pupil plane of the projection optics 17 may restrict the range of beam angles that impinge on the wafer plane 18, where the largest possible angle defines the numerical aperture of the projection optics NA=n sin(Gmax), wherein n is the refractive index of the media between the substrate and the last element of the projection optics 17, and Gmax is the largest angle of the beam exiting from the projection optics 17 that can still impinge on the wafer plane 18.

In the present document, the terms “radiation” or “beam” are used to encompass all types of electromagnetic radiation, including ultraviolet radiation (e.g., with a wavelength of 365, 248, 193, 157 or 126 nm) and EUV (extreme ultra-violet radiation, e.g., having a wavelength in the range of about 3-100 nm).

Illumination optics 16 may include optical components for shaping, adjusting and/or projecting radiation from the radiation source 12 before the radiation passes the photolithography mask 14. Projection optics 17 may include optical components for shaping, adjusting and/or projecting the radiation after the radiation passes the photolithography mask 14. The illumination optics 16 exclude the light source 12, the projection optics exclude the photolithography mask 14.

Illumination optics 16 and projection optics 17 may comprise various types of optical systems, including refractive optics, reflective optics, apertures and catadioptric optics, for example. Illumination optics 16 and projection optics 17 may also include components operating according to any of these design types for directing, shaping or controlling the projection beam of radiation, collectively or singularly.

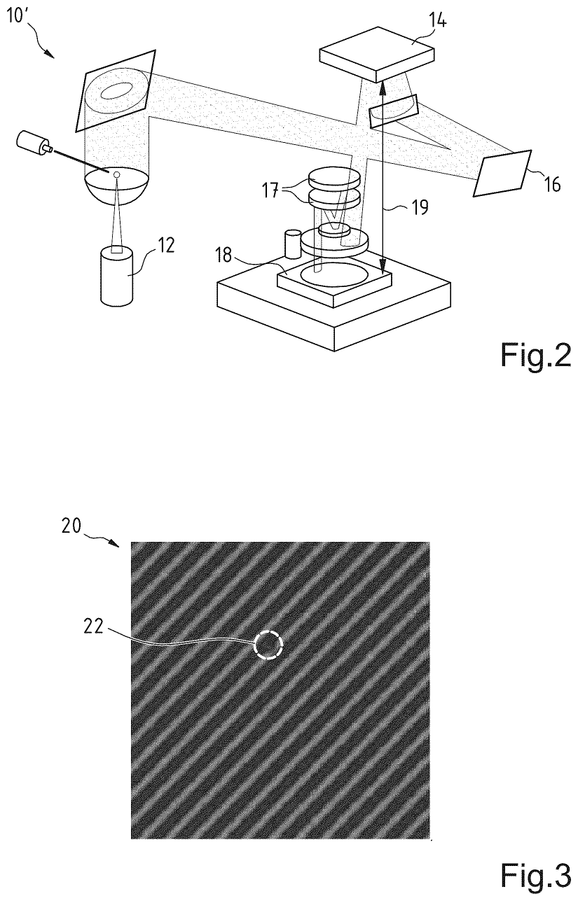

FIG. 2 illustrates an exemplary reflection-based photolithography system 10′, e.g., an extreme ultraviolet light (EUV) lithography system. Major components are a radiation source 12, which may be a laser plasma light source, illumination optics 16 which, for example, define the partial coherence and which may include optics that shape radiation from the radiation source 12, a photolithography mask 14, and projection optics 17 that project an image of the photolithography mask model 92, the design pattern, onto a wafer plane 18. An adjustable filter or aperture at the pupil plane of the projection optics 17 may restrict the range of beam angles that impinge on the wafer plane 18, where the largest possible angle defines the numerical aperture of the projection optics NA=n sin(Gmax), wherein n is the refractive index of the media between the substrate and the last element of the projection optics 17, and Gmax is the largest angle of the beam exiting from the projection optics 17 that can still impinge on the wafer plane 18.

FIG. 3 illustrates an image 20 of a photolithography mask 14 that contains a defect 22. According to the techniques described herein, various imaging modalities may be used to acquire the image. Images can comprise single-channel images or multi-channel images, e.g., focus stacks. For instance, it is possible that the image includes 2-D images. It is possible to employ a multi beam scanning electron microscope (mSEM). mSEM employs multiple beams to acquire contemporaneously images in multiple fields of view. For instance, a number of not less than 50 beams could be used or even not less than 90 beams. Each beam covers a separate portion of a surface of the photolithography mask. Thereby, a large image is acquired within a short duration of time. Typically, contemporary machines acquire 4.5 gigapixels per second. Other examples for images including 2D images relate to imaging modalities such as optical imaging, phase-contrast imaging, x-ray imaging, etc. It is also possible that the image is a volumetric 3-D dataset, which can be processed slice-by-slice or as a three-dimensional volume. Here, a crossbeam imaging system including a focused-ion beam (FIB) source, an atomic force microscope (AFM) or a scanning electron microscope (SEM) could be used. Furthermore, magnetic resonance (MR) images, ultrasound images or computed tomography (CT) images could be used. Multimodal images may be used, e.g., a combination of x-ray imaging and SEM. The image can be an aerial image acquired by an aerial image measurement system. An aerial image is the radiation intensity distribution at substrate level. It can be used to simulate the radiation intensity distribution generated by a photolithography mask during the photolithography process. The aerial image measurement system can, for example, be equipped with a staring array sensor or a line-scanning sensor or a time-delayed integration (TDI) sensor.

For defect detection, machine learning models are a popular choice to obtain high quality results at short computation times. Machine learning models are trained using training data, i.e., examples, and, thus, independently derive their knowledge from the training data instead of requiring a user to define rules for defect detection. In this way, optimal defect detection results can be obtained automatically in a data-driven way. Thus, the use of machine learning models increases the recall and precision of the defect detection methods and reduces the user effort.

However, machine learning models, in particular deep learning models, require large amounts of training data, which is not always available. In addition, training a machine learning model can take up to several days or weeks depending on the complexity of the model. Furthermore, the machine learning model can only apply the knowledge derived from the training data. If conditions change, the machine learning model must be re-trained.

Conditions can change, for example, if the optical properties of the photolithography masks change during its use in photolithography processes, e.g., by EUV exposure tools. Conditions can also change if the photolithography mask is exchanged, as different photolithography masks can vary not only in their design but also in their material. Conditions also change if the defect detection method is carried out on a different inspection system, e.g., on the same type of inspection system or on a different type of inspection system. In all of these cases a fast re-training of the machine learning model for defect detection is required. However, training data is usually unavailable or very scarce in case of changing conditions.

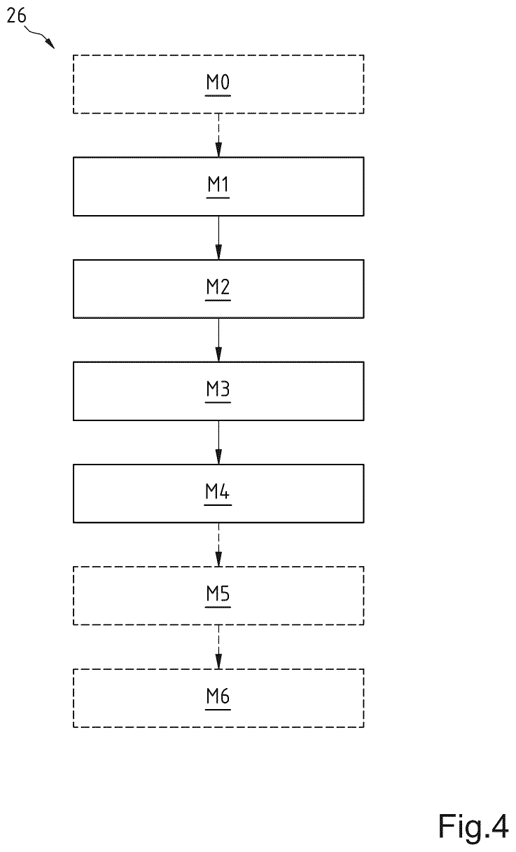

To allow for a re-training of the machine learning model, FIG. 4 shows a flowchart of a method 24 for re-training a pre-trained machine learning model for defect detection in an image of a photolithography mask according to an embodiment of the invention. The method for re-training a pre-trained machine learning model for defect detection in an image of a photolithography mask comprises: a. acquiring adjustment images of one or more photolithography masks using an inspection system, wherein the inspection system is configured for acquiring images of photolithography masks in a step M1; b. adjusting at least one parameter of a simulation of the inspection system using the adjustment images in a step M2; c. generating training images of one or more photolithography masks using the adjusted simulation of the inspection system in a step M3; and d. re-training the machine learning model for defect detection using the generated training images in a step M4. The re-trained machine learning model can be used for defect detection in an image of a photolithography mask acquired by the inspection system in a step M6.

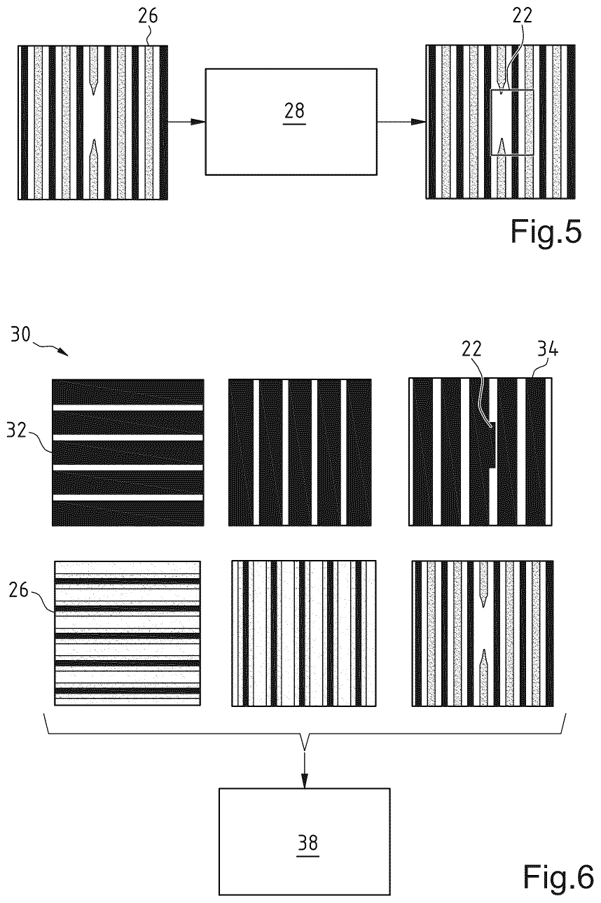

As illustrated in FIG. 5, the trained machine learning model 28 for defect detection obtains an image 26, in this case an aerial image, as input and maps the image 26 to none, one or more defects 22 or representations thereof. A supervised machine learning model for defect segmentation can use known machine learning segmentation architectures, for example, a U-Net or a Segformer as described in the paper “SegFormer: Simple and Efficient Design for Semantic Segmentation with Transformers, Enze Xie, Wenhai Wang, Zhiding Yu, Anima Anandkumar, Jose M. Alvarez, Ping Luo, arXiv 2105.15203, 2021”. A supervised machine learning model for defect localization can use known machine learning object detection architectures, e.g., Center Net or YOLO. Center Net is a machine learning based object detector based on keypoint triplets, wherein two keypoints represent opposite corners of a bounding box. A bounding box proposal is preserved if an additional keypoint of the same class is found in the center region of the bounding box. YOLO is a very fast machine learning based object detector that uses a fully convolutional neural network for bounding box prediction. The image is subdivided into grid cells, and for each grid cell a specified number of bounding boxes is predicted that can be larger than the grid cell. Bounding boxes are preserved based on their class probabilities and bounding box confidences. By using bounding box based object detectors, areas comprising a defect can be discriminated from defect-free areas. For defect detection, reference-based registration and detection machine learning architectures as, for example, disclosed in German patent application 10 2023 104 378.1, or reference-based die-to-database machine learning architectures via known design-to-image simulation algorithms can be used. Furthermore, self-supervised or reference-free anomaly detection machine learning models that do not require annotated training images can be used for defect detection, e.g., autoencoders.

In an optional step M0 before step M1, the method can further comprise pre-training the machine learning model using pre-training images. The pre-training of the machine learning model may be used to already approximately adapt the parameters of the machine learning model to the task at hand, thereby reducing the required number of training images and increasing the accuracy of the trained machine learning model. However, an already pre-trained machine learning model may also be downloaded from a website or a data storage, or it may be available from previous applications. The pre-training images can comprise at least one image acquired by an inspection system. The at least one image can be acquired using the same inspection system as in step M1 for acquiring the adjustment images, or it can be acquired using a different inspection system or even a different type of inspection system. For example, the machine learning model can be pre-trained using acquired images of an inspection system at a first site, and it can be re-trained using acquired images of a different inspection system at a second site. Even if the inspection systems are of the same type, the parameters or conditions at the two sites may differ requiring a re-training of the machine learning model.

Alternatively or additionally, the pre-training images 31 can comprise at least one simulated image generated using the simulation of the inspection system. The simulation of the inspection system can be used with initial simulation parameters to generate the pre-training images. These initial simulation parameters can be adapted to new conditions later on using the adjustment images in step M2.

In an optional step M5, a final re-training of the re-trained machine learning model after step d. of the method can be carried out using few acquired training images of the inspection system, preferably including defect annotations. This procedure may be particularly beneficial if the simulation of the inspection system is not fully realistic or if the adjusted simulation parameters do not fully fit and the simulated images are, thus, not fully realistic. In these cases, a final re-training with acquired training images of the inspection system would reduce possible shortcomings of the re-trained machine learning model due to suboptimal simulated training images. Thus, the accuracy of the predictions of the re-trained machine learning model could be improved.

According to an aspect of the invention, the simulation of the inspection system comprises simulating the image acquisition process for a photolithography mask, in particular by using a design of the photolithography mask. The design is used to generate an image, e.g., an aerial image, of the corresponding photolithography mask. Simulating the image acquisition process for a photolithography mask can, for example, comprise using an optically inspired simulation based on physics-based models, e.g., rigorous simulations or Kirchhoff simulations. For these simulations, the simulation parameters could comprise optical parameters such as a light source intensity or a mask thickness. Alternatively, simulating the image acquisition process could comprise using a data-driven model, e.g., a machine learning model that is trained to predict an image from a design of a photolithography mask. In this case, the simulation parameters could comprise the trainable parameters of the machine learning model. Alternatively, hybrid models could be used that combine an optically inspired simulation based on a physical model and a machine learning model. In this case, the simulation parameters could include a combination of optical parameters and machine learning parameters.

Aerial images can, for example, be simulated using a physical model for generating an aerial image from a design. This leads to accurate results but is often time consuming. Among these methods, there are rigorous simulation methods such as finite difference time domain (FDTD) or rigorous coupled wave analysis (RCWA) that are known to a person skilled in the art. Since they require long computation times, fast approximations such as the thin element approximation (TEA) can be used. The thin element approximation (TEA) assumes that the thickness of the structures on the photolithography mask is very small compared to the wavelength, and that the widths of the structures on the photolithography mask are very large compared to the wavelength. However, as photolithographic processes use radiation of shorter and shorter wavelengths, and the structures on the patterning device become smaller and smaller and grow into the vertical dimension, these assumptions do not hold anymore, and mask 3D effects must be taken into account. Therefore, the results of the TEA method are less accurate but much faster to obtain than rigorous simulation results.

The simulation of the inspection system can also comprise a machine learning model for simulating the image acquisition process. FIG. 6 shows a machine learning model 38 that is trained for simulating an image acquisition process in order to generate simulated pre-training images 31 in step M0 or training images 33 in step M3. The training images 30 for the machine learning model that simulates the image acquisition process comprise designs 32 and corresponding images 26, e.g., aerial images. The corresponding images 26 are preferably acquired using some image acquisition system. During training, an objective function is minimized. The objective function can, for example, minimize the deviation of the images generated by the machine learning model from the corresponding images 26.

In another example, physics-based models can be used to simulate the image acquisition process, e.g., the propagation of incident electromagnetic waves through the photolithography masks in case of aerial images. Machine learning models can, optionally, be subsequently used to improve on these results. To obtain realistic simulated images, for example, noise, focus variations or deviations from ideal structures such as line edge roughness, thickness variations of structures or corner rounding, etc., can be applied to the simulated images.

Preferably, at least some of the training images 30 are simulated images of designs containing uncommon structures. Uncommon structures are structures that are usually not part of a design, e.g., defects, design deviations that do not necessarily classify as defect such as small variations in design structures, e.g., thickness variations of structures, corner rounding, etc., or types of structures not included in the training images, e.g., in case only designs containing lines and spaces are contained in the training images, uncommon structures could comprise holes, crossings, assist features, complex polygons, etc. For example, the rightmost design 32 in FIG. 6 contains a defect 22 in the form of a protrusion or intrusion. In this way, the simulation 44 of the inspection system 50 is able to simulate the image acquisition process for all kinds of designs, including designs containing uncommon structures.

Using the simulation of the inspection system, training images for the machine learning model for defect detection can then be simulated quickly and easily by use of the simulated image acquisition process (e.g., using physical models and/or machine learning models). Artificial defects 22 can be added to the designs 32 to obtain defective designs 34. From these artificial defects 22 defect annotations 36 can be easily generated together with the training images. These can be used to effectively re-train the machine learning model 28 for defect detection in a supervised way. Apart from defects 22, further uncommon structures can also be added to the designs 32 to generate training images. In this way, the machine learning model 28 for defect detection learns to distinguish between defects 22 and uncommon structures that do not qualify as defects 22.

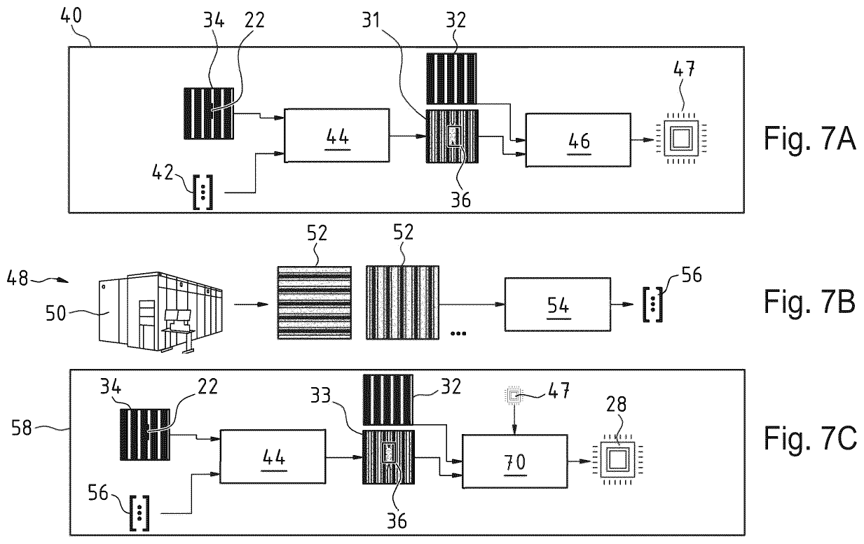

FIG. 7A to 7C illustrate the method according to the invention for effectively re-training a machine learning model 28 for defect detection in an image of a photolithography mask.

FIG. 7A illustrates a pre-training stage 40 according to the optional step M0 for pre-training the machine learning model 28 using pre-training images 31. The simulation 44 of the inspection system 50 comprises a simulation of the image acquisition process given a design 32 of a photolithography mask, e.g., a physics-based model or a machine learning model 38 as illustrated in FIG. 6.

To generate the pre-training images 31, preferably the simulation 44 of the inspection system 50 is used with initial simulation parameters 42, e.g., the trained machine learning model 38 with initial parameters in FIG. 6 or a physics-based model with initial parameters. The initial simulation parameters can be selected in various ways. For example, parameters of the inspection system 50 with a high likelihood can be used, or average parameters of the inspection system 50 can be used, or expected parameters of the inspection system 50 can be used, or random parameters drawn from pre-specified ranges of the parameters of the inspection system can be used. In case possible or likely modifications of the conditions are already known, e.g., the type of inspection system or frequently used types of inspection systems, illumination conditions at a second site or typical illumination conditions, the types of photolithography masks used at a second site or typical types of photolithography masks, etc., these can be taken into account when selecting the initial simulation parameters 42 to generate pre-training images 31 for training the simulation 44 of the inspection system 50. Different sets of initial simulation parameters 42 can also be used to generate diverse pre-training images 31 for pre-training the machine learning model 28. In this way, the machine learning model can already be closely adapted to modified conditions.

Additionally or alternatively, acquired images of an inspection system 50 can be used as pre-training images 31 for pre-training the machine learning model 28. Several options are conceivable here. For example, at least some of the pre-training images 31 and at least some of the adjustment images 52 can be acquired using different inspection systems 50 of the same type, but with slightly different behaviors due to variations within predefined tolerances of the inspection systems 50. In another example, at least some of the pre-training images 31 and at least some of the adjustment images 52 are acquired using inspection systems 50 of different types yielding images of different modalities, e.g., aerial images and SEM images. Even though these images are of different modalities, they can contain information about the same photolithography mask. In another example, at least some of the pre-training images 31 and at least some of the adjustment images 52 are acquired by the same inspection system 50, but for different photolithography masks, e.g., with different materials, different designs, etc. In another example, at least some of the pre-training images 31 and at least some of the adjustment images 52 are acquired by the same inspection system 50 for the same photolithography mask, but at different time periods, e.g., at least some of the pre-training images 31 were acquired days, weeks, months or even years before at least some of the adjustment images 52, or vice versa. In this way, acquired images can be used in addition or instead of simulated pre-training images 31 for pre-training the machine learning model.

Preferably, at least some of the designs are defective designs 34 including one or more defects 22. Simulated images of the defective designs 34 can be used to pre-train the machine learning model 28 for defect detection. To obtain a defective design 34, a defect-free design 32 can be modified by adding one or more artificial defects 22. Alternatively, a design including a defect can be used. Using the simulation 44 of the inspection system 50, e.g., with initial simulation parameters 42, an image of the defective design 34 can be simulated that is used as pre-training image 31 for pre-training the machine learning model 28 for defect detection. Preferably, at least some of the simulated pre-training images 31 comprise defect annotations 36. As the defects 22 are artificially generated, the corresponding defect annotations 36 can be easily included in the pre-training images 31. For example, the modification of the defect-free design 32 can be used to obtain defect annotations 36 for the simulated image of the defective design 34. Alternatively, the difference between a simulated image of the defect-free design and the simulated image of the defective design 34 can be used to obtain defect annotations 36. Defect annotations 36 indicate the presence, the location, the extent and/or the type of defect, etc., e.g., in the form of bounding boxes, pixel annotations, defect classes, etc. The pre-training images 31 can also include acquired images with or without defect annotations 36. The pre-training images 31 can also include acquired or simulated images without defects.

The pre-training images 31 are used for pre-training the machine learning model 28 for defect detection in a pre-training step 46, yielding a pre-trained machine learning model 47. The defect-free design 32 corresponding to the defective design 34 can, optionally, be used as additional input of the machine learning model 28 for defect detection.

FIG. 7B illustrates an adjustment stage 48 for adjusting the parameters of the simulation 44 of the inspection system 50 to modified conditions, e.g., at a different site, using a different inspection system 50 or a different type of inspection system 50, different machine settings, e.g., illumination settings, different photolithography masks, different materials, different designs 32, different image properties, e.g., noise, distortions, intensity, brightness, contrast, etc. To this end, adjustment images 52 are acquired using the inspection system 50. As no re-training of the pre-trained machine learning model 47 is intended at this stage, but only the adjustment of the simulation parameters of the inspection system 50, acquiring a small number of adjustment images 52, e.g., less than 1%, preferably less than 0.1%, more preferably less than 0.01%, most preferably less than 0.001% of the number of pre-training images used for pre-training the machine learning model 28, or of the training images used for re-training the machine learning model 28, is sufficient. Preferably, at least some of the adjustment images 52 are acquired using photolithography masks having the same design 32 as the designs 32 underlying the pre-training images 31 used for pre-training the machine learning model 28. In this way, adjusting the parameters is simplified and yields more accurate results. The simulation parameters of the simulation 44 of the inspection system 50 are then adjusted to the acquired adjustment images 52 in a parameter adjustment step 54, yielding adjusted simulation parameters 56.

The parameter adjustment step 54, preferably, comprises solving an optimization problem. In case the adjustment images xᵢ comprise designs dᵢ of the corresponding photolithography masks, the parameter adjustment step 54 for adjusting the parameters θₖ of the simulation T of the inspection system can, for example, be carried out by solving the following optimization problem that minimizes a loss function L:

$${θ}_{T} = arg {min}_{θ} {\sum }_{i} L ( {x}_{i} , T ( {d}_{i} , θ ) ) .$$

The loss function measures the difference between the adjustment image xᵢ and the simulated image T(dᵢ, θ) for the corresponding design dᵢ and given one or more simulation parameters θ. Thus, the simulation parameters 42 are adjusted such that the simulated images from the designs match the adjustment images as well as possible. The loss function can contain further terms, e.g., regularization terms. Alternatively, in particular in case corresponding designs dᵢ for the adjustment images xᵢ are not available, the loss function can maximize the similarity (or minimize the dissimilarity) of a distribution of the adjustment images xᵢ and a distribution of the simulated images for some available designs, e.g., by minimizing the Kullback-Leibler divergence or other stochastic measures, or by comparing image statistics using, e.g., signal to noise ratios, contrast ratios, blurriness, edge strengths, etc. Alternatively, classification methods such as discriminators used in generative adversarial network (GAN) approaches can be used to learn to discriminate between adjustment images xᵢ and simulated images T(dᵢ, θ). The parameters θ of the simulation 44 of the inspection system 50 can be modified until the discriminator cannot discriminate between the adjustment images xᵢ and the simulated images T(dᵢ, θ) anymore, that is, if the classifier confusion over the two sets of images xᵢ and T(dᵢ, θ) is maximized. The discriminator can be trained on patches of the images. In case the simulation 44 of the inspection system 50 allows to compute gradients with respect to the simulation parameters, the simulation parameters can be adjusted by solving an optimization problem using gradient descent approaches.

To simplify the optimization problem, prior knowledge can be used. For example, not all simulation parameters need to be estimated as some of them can be known in advance, e.g., an illumination parameter, a mask material, etc. Such parameters can, for example, be loaded from a database or they can be indicated by a user. Furthermore, for many simulation parameters parameter value ranges or probability distributions over parameter values can be specified. Parameter value ranges can be used in the optimization problem to restrict the values of the simulation parameters using constraints. Probability distributions over parameter values can, for example, be included in the objective function of the optimization problem. The probability distributions can be maximized, or their negative log likelihood can be minimized:

$$L ( θ ) = o ( θ ) - log p ( {θ}_{k} ) .$$

Here, L(θ) indicates a parameterized loss function, o(θ) some parameterized objective function and p(θₖ) a probability distribution over parameter θₖ that is maximized due to the negative log likelihood.

FIG. 7C illustrates the re-training of the pre-trained machine learning model 47 in a re-training stage 58. Using the adjusted simulation parameters 56, the simulation 44 of the inspection system 50 is applied to generate large amounts of training images 33 from designs 32 and derived defective designs 34 of photolithography masks. The training images 33 are used for re-training the pre-trained machine learning model 47 for defect detection. The pre-training images 31 and the training images 33, preferably, rely, at least partially, on the same designs. But they can also rely on different designs. As the training images 33 are simulated, they can be generated automatically at low computation times and requiring low user effort. The generated training images 33 can be targeted to specific defects 22 or design types. In this way, a re-training 70 of the machine learning model with respect to specific defect types or design types is possible. Alternatively, the generated training images 33 can systematically cover a range of defect types or design types, allowing for an efficient and fast re-training of the machine learning model 28.

At least some of the generated training images 33 in step c. comprise simulated images of defective designs 34 and corresponding defect annotations 36, the simulated images being obtained by applying the simulation 44 of the inspection system 50 to the defective designs 34. To obtain a defective design 34, a defect-free design 32 can be modified by adding one or more artificial defects 22. Alternatively, a design including a defect can be used. Using the simulation 44 of the inspection system 50 after adjusting the parameters, an image of the defective design 34 can be simulated. Preferably, at least some of the simulated training images 33 comprise defect annotations 36. As the defects 22 are artificially generated, the corresponding defect annotations 36 can be easily included in the training images 33. For example, the modification of the defect-free design 32 can be used to obtain defect annotations 36 for the simulated image of the defective design 34. Alternatively, the difference between a simulated image of the defect-free design and the simulated image of the defective design 34 can be used to obtain defect annotations 36. Defect annotations 36 indicate the presence, the location, the extent and/or the type of defect, etc., e.g., in the form of bounding boxes, pixel annotations, defect classes, etc. The training images 33 can also include acquired images with or without defect annotations 36. The training images 33 can also include acquired or simulated images without defects.

The generation of pre-training images and training images and the pre-training and re-training of the machine learning model can, for example, be carried out on a computer, on a cluster, in a distributed system or in a cloud. To this end, the use of powerful hardware is beneficial, e.g., graphics processing units (GPUs) or tensor processing units (TPUs) can be used to accelerate the algorithms. A lot of random access memory (RAM) and storage space with fast input/output (IO) is also beneficial to reduce computation times. The hardware does not need to be physically connected to the inspection system, but it can be beneficial.

The pre-training of the machine learning model can be carried out in an environment that strongly differs from the environment for re-training the machine learning model. For example, the pre-training of the machine learning model can be carried out in a development environment at a first site using large computer clusters, dedicated hardware or even cloud instances. In contrast, the re-training of the machine learning model can be carried out in an application environment, e.g., at a second site with reduced hardware or requiring specific confidentiality standards, e.g., at a customer's site. Using the method according to the invention, the pre-training of the machine learning model can be carried out thoroughly using large amounts of pre-training images in the development environment, whereas the re-training of the machine learning model can be carried out using only very few acquired adjustment images, simulated training images and, optionally, a small number of acquired training images in the application environment.

The above described method for re-training of a machine learning model for defect detection in case of modified conditions can be carried out iteratively. Each time conditions are modified, the machine learning model requires re-training, for example, each time a different photolithography mask is loaded by the inspection system. To this end, steps a. to d. can be carried out repeatedly. Instead of re-training the machine learning model from scratch or from the pre-trained machine learning model 47, it can be beneficial to use an already re-trained machine learning model as a pre-trained machine learning model to incorporate further modified conditions as this may require fewer adjustments. For example, in case the machine learning model was pre-trained at a first site, e.g., a production site, and shipped to a second site, e.g., at a consumer, less adjustments might be required if an already re-trained machine learning model is used for further re-training than if the shipped pre-trained machine learning model from the first site is used for re-training.

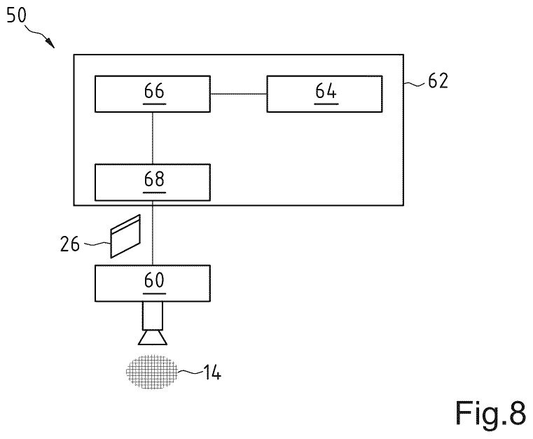

An inspection system 50 for detecting defects 22 in an image 26 of a photolithography mask 14 according to a third embodiment of the invention is illustrated in FIG. 8. The inspection system 50 comprises: an image acquisition unit 60 configured to acquire images 26 of photolithography masks 14; and a data analysis device 62 comprising at least one memory 64 and at least one processor 66 configured to perform the steps of a method according to an embodiment of the invention.

The image acquisition unit 60 provides the image 26 to the data analysis device 62. For example, the image acquisition unit 60 can include one or more image sensors, such as charge coupled device (CCD) sensors or complementary metal oxide semiconductor (CMOS) sensors, each having an array of individually addressable sensing elements (or pixels). The image acquisition unit 60 can include electronic circuitry for processing signals from the one or more image sensors. The processor 66 can be implemented, e.g., as a central processing unit (CPU), GPU or TPU. The processor 66 can receive the image 26 via an interface 68. The processor 66 can load program code from a memory 64, e.g., program code for executing a method for detecting defects 58 according to an embodiment of the invention as described above. The processor 66 can execute the program code.

A system for re-training a machine learning model for defect detection in an image of a photolithography mask according to a fourth embodiment of the invention comprises: an image acquisition unit configured to acquire images of photolithography masks; and a data analysis device comprising at least one memory and at least one processor configured to perform the steps of a method for re-training a machine learning model for defect detection in an image of a photolithography mask according to an embodiment of the invention. The image acquisition unit can be used to acquire adjustment images and, optionally, training images. The data analysis device obtains a pre-trained machine learning model that is re-trained as described above.

In some implementations, a system for repairing a photolithography mask (e.g., 14) having integrated circuit patterns can be used to repair the defects (e.g., 22) in the photolithography mask after the defects are detected using the methods described above. The repair system can be configured to perform an electron beam-induced etching and/or deposition on the mask to repair defects detected by the data analysis device 62. The repair system can include, e.g., an electron source, which emits an electron beam that can be used to perform electron beam-induced etching or deposition on the mask. The repair system can include mechanisms for deflecting, focusing and/or adapting the electron beam. The repair system can be configured such that the electron beam is able to be incident on a defined point of incidence on the mask.

The repair system can include one or more containers for providing one or more deposition gases, which can be guided to the mask via one or more appropriate gas lines. The repair system can also include one or more containers for providing one or more etching gases, which can be provided on the mask via one or more appropriate gas lines. Further, the repair system can include one or more containers for providing one or more additive gases that can be supplied to be added to the one or more deposition gases and/or the one or more etching gases. The repair system can include a user interface to allow an operator to, e.g., operate the repair system and/or read out data.

In some implementations, each processor 66 can include one or more processor cores, and each processor core can include logic circuitry for processing data. For example, a processor can include an arithmetic and logic unit (ALU), a control unit, and various registers. Each processor can include cache memory. Each processor can include a system-on-chip (SoC) that includes multiple processor cores, random access memory, graphics processing units, one or more controllers, and one or more communication modules. Each processor can include millions or billions of transistors.

In some implementations, the data analysis device 62 can include one or more data processors for processing data, one or more storage devices for storing data, and/or one or more computer programs including instructions that when executed by the one or more computers cause the one or more computers to carry out the processes. The one or more computers can include one or more input devices, such as a keyboard, a mouse, a touchpad, and/or a voice command input module, and one or more output devices, such as a display, and/or an audio speaker.

In some implementations, the one or more computing devices can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

A computer program can be written in any form of programming language, including compiled or interpreted languages, and it can be deployed in any form, including as a stand-alone program or as a module, component, subroutine, or other unit suitable for use in a computing environment.

For example, the one or more computers can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer system include one or more processors for executing instructions and one or more storage area devices for storing instructions and data. Generally, a computer system will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, flash storage devices, and solid state drives; magnetic disks, e.g., internal hard disks or removable disks; magneto-optical disks; and CD-ROM, DVD-ROM, and/or Blu-ray discs.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one processor, at least one data storage system (including volatile and non-volatile memory and/or storage elements), at least one wired or wireless input device or port, and at least one wired or wireless output device or port.

In some implementations, the software may be provided on a medium, such as CD-ROM, DVD-ROM, Blu-ray disc, a solid state drive, or a hard drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage media or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

Reference throughout this specification to “an embodiment” or “an example” or “an aspect” means that a particular feature, structure or characteristic described in connection with the embodiment, example or aspect is included in at least one embodiment, example or aspect. Thus, appearances of the phrases “according to an embodiment,” “according to an example” or “according to an aspect” in various places throughout this specification are not necessarily all referring to the same embodiment, example or aspect, but may refer to different embodiments, examples, or aspects. Furthermore, the particular features or characteristics may be combined in any suitable manner, as would be apparent to one of ordinary skill in the art from this disclosure, in one or more embodiments.

Furthermore, while some embodiments, examples or aspects described herein include some but not other features included in other embodiments, examples or aspects combinations of features of different embodiments, examples or aspects are meant to be within the scope of the claims, and form different embodiments, as would be understood by those skilled in the art.

The following clauses contain preferred embodiments of the invention:
1. A method 24 for re-training a pre-trained machine learning model 28 for defect detection in an image 26 of a photolithography mask 14, the method comprising:
   a. Acquiring adjustment images 52 of one or more photolithography masks 14 using an inspection system 50, wherein the inspection system 50 is configured for acquiring images 26 of photolithography masks 14;
   b. Adjusting at least one parameter of a simulation 44 of the inspection system 50 using the adjustment images 52;
   c. Generating training images 33 of one or more photolithography masks 14 using the adjusted simulation 44 of the inspection system 50; and
   d. Re-training the machine learning model 28 for defect detection using the generated training images 33.
2. A method 24 for defect detection in an image 26 of a photolithography mask 14 using a pre-trained machine learning model 28, the method comprising:
   a. Acquiring adjustment images 52 of one or more photolithography masks 14 using an inspection system 50, wherein the inspection system 50 is configured for acquiring images 26 of photolithography masks 14;
   b. Adjusting at least one parameter of a simulation 44 of the inspection system 50 using the adjustment images 52;
   c. Generating training images 33 of one or more photolithography masks 14 using the adjusted simulation 44 of the inspection system 50;
   d. Re-training the machine learning model 28 for defect detection using the generated training images 33;
   e. Applying the re-trained machine learning model 44 for defect detection to an image 26 of a photolithography mask 14 acquired by the inspection system 50.
3. The method of clause 1 or 2, wherein adjusting the at least one parameter of the simulation 44 of the inspection system 50 in step b. comprises solving an optimization problem.
4. The method of clause 3, wherein for at least one adjustment image 52 a design 32 of the corresponding photolithography mask 14 is available, wherein the simulation 44 of the inspection system 50 simulates the image acquisition process for a photolithography mask 14 using a design 32 of the photolithography mask 14, and wherein solving the optimization problem comprises minimizing a deviation of one or more adjustment images 52 from the simulated images of the corresponding designs 32.
5. The method of clause 3 or 4, wherein solving the optimization problem comprises maximizing the similarity of the distribution of adjustment images 52 and a distribution of simulated images obtained using the simulation 44 of the inspection system 50.
6. The method of any one of clauses 3 to 5, wherein gradients of the simulation 44 of the inspection system 50 with respect to the at least one parameter are derived, and wherein solving the optimization problem comprises using a gradient descent approach using the derived gradients.
7. The method of any one of the preceding clauses, further comprising, before step a., pre-training the machine learning model 28 using pre-training images 31 that comprise at least one simulated image generated using the simulation 44 of the inspection system 50.
8. The method of any one of the preceding clauses, further comprising, before step a., pre-training the machine learning model 28 using pre-training images 31 that comprise at least one image acquired by an inspection system 50.
9. The method of any one of the preceding clauses, wherein at least some training images 33 comprise defect annotations 36.
10. The method of any one of the preceding clauses, wherein the simulation 44 of the inspection system 50 simulates the image acquisition process for a photolithography mask 14.
11. The method of clause 10, wherein the simulation 44 of the inspection system 50 comprises simulating the image acquisition process using a design 32 of the photolithography mask 14.
12. The method of clause 11, wherein the generated training images 33 comprise simulated images of defective designs 34 and/or of designs containing uncommon structures and corresponding defect annotations 36, the simulated images being obtained by applying the simulation 44 of the inspection system 50 to the defective designs 34 and/or to the designs containing uncommon structures.
13. The method of any one of the preceding clauses, wherein prior knowledge is used for adjusting the at least one parameter of the simulation of the inspection system in step b.
14. The method of any one of the preceding clauses, wherein the majority of adjustment images 52 differ from pre-training images 31 used for pre-training the machine learning model 28 in at least one aspect from the group comprising the inspection system, the image acquisition time period, the photolithography mask.
15. The method of any one of the preceding clauses, wherein the pre-training of the machine learning model 28 is carried out on a first computer system and at least step d. is carried out on a second computer system.
16. The method of any one of the preceding clauses, wherein the number of adjustment images 52 is less than 1% of the number of pre-training images 31 used for pre-training the machine learning model 28, preferably less than 0.1%, more preferably less than 0.01%, most preferably less than 0.001%.
17. The method of any one of the preceding clauses, wherein steps a. to d. are iterated.
18. The method of any one of the preceding clauses, wherein the simulation 44 of the inspection system 50 comprises a physical simulation of the propagation of electromagnetic waves within a photolithography mask.
19. The method of any one of the preceding clauses, wherein the simulation 44 of the inspection system 50 comprises the application of a trained machine learning model 38.
20. A method for detecting defects 22 in an image 26 of a photolithography mask 14 in an inspection system 50, the method comprising the use of a machine learning model 28 for defect detection re-trained according to any one of the preceding clauses.
21. An inspection system 50 for detecting defects 22 in an image 26 of a photolithography mask 14 comprising:
   a. an image acquisition unit 60 configured to acquire images 26 of photolithography masks 14; and
   b. a data analysis device 62 comprising at least one memory 64 and at least one processor 66 configured to perform the steps of a method for detecting defects 22 in an image 26 of a photolithography mask 14 according to clause 20.

In a general aspect, the invention relates to a method for re-training a pre-trained machine learning model 28 for defect detection in an image of a photolithography mask, the method comprising: acquiring adjustment images 52 of one or more photolithography masks using an inspection system 50; adjusting at least one parameter of a simulation 44 of the inspection system 50 using the adjustment images 52; generating training images 33 of one or more photolithography masks using the adjusted simulation 44 of the inspection system 50; and re-training the machine learning model 28 for defect detection using the generated training images 33, for use of the re-trained machine learning model 28 for defect detection in an image of a photolithography mask acquired by the inspection system 50. The invention also relates to a method and an inspection system for defect detection.

### REFERENCE NUMBER LIST

10, 10′ Photolithography system
12 Radiation source
14 Photolithography mask
16 Illumination optics
17 Projection optics
18 Wafer plane
19 Projection section
20 Image
22 Defect
24 Method
26 Image
28 Machine learning model
30 Training images
31 Pre-training images
32 Design
33 Training images
34 Defective design
36 Defect annotation
38 Machine learning model
40 Pre-training stage
42 Initial simulation parameters
44 Simulation
46 Pre-training step
48 Adjustment stage
50 Inspection system
52 Adjustment image
54 Parameter adjustment step
56 Adjusted simulation parameters
58 Re-training stage
60 Image acquisition unit
62 Data analysis device
64 Memory
66 Processor
68 Interface
70 Re-training

What is claimed is:

1. A method for re-training a pre-trained machine learning model for defect detection in an image of a photolithography mask, the method comprising:
a. acquiring adjustment images of one or more photolithography masks using an inspection system, wherein the inspection system is configured for acquiring images of photolithography masks;
b. adjusting at least one parameter of a simulation of the inspection system using the adjustment images;
c. generating training images of one or more photolithography masks using the adjusted simulation of the inspection system; and
d. re-training the machine learning model for defect detection using the generated training images.

2. The method of claim 1, wherein adjusting the at least one parameter of the simulation of the inspection system in step b. comprises solving an optimization problem.

3. The method of claim 2, wherein for at least one adjustment image a design of the corresponding photolithography mask is available, wherein the simulation of the inspection system simulates the image acquisition process for a photolithography mask using a design of the photolithography mask, and wherein solving the optimization problem comprises minimizing a deviation of one or more adjustment images from the simulated images of the corresponding designs.

4. The method of claim 2, wherein solving the optimization problem comprises maximizing the similarity of the distribution of adjustment images and a distribution of simulated images obtained using the simulation of the inspection system.

5. The method of claim 2, wherein gradients of the simulation of the inspection system with respect to the at least one parameter are derived, and wherein solving the optimization problem comprises using a gradient descent approach using the derived gradients.

6. The method of claim 1, further comprising, before step a., pre-training the machine learning model using pre-training images that comprise at least one simulated image generated using the simulation of the inspection system.

7. The method of claim 1, further comprising, before step a., pre-training the machine learning model using pre-training images that comprise at least one image acquired by an inspection system.

8. The method of claim 1, wherein at least some training images comprise defect annotations.

9. The method of claim 1, wherein the simulation of the inspection system simulates the image acquisition process for a photolithography mask.

10. The method of claim 9, wherein the simulation of the inspection system comprises simulating the image acquisition process using a design of the photolithography mask.

11. The method of claim 10, wherein the generated training images comprise simulated images of defective designs and corresponding defect annotations, the simulated images being obtained by applying the simulation of the inspection system to the defective designs.

12. The method of claim 1, wherein prior knowledge is used for adjusting the at least one parameter of the simulation of the inspection system in step b.

13. The method of claim 1, wherein the majority of adjustment images differ from pre-training images used for pre-training the machine learning model in at least one aspect from the group comprising the inspection system, the image acquisition time period, the photolithography mask.

14. The method of claim 1, wherein the pre-training of the machine learning model is carried out on a first computer system and at least step d. is carried out on a second computer system.

15. The method of claim 1, wherein the number of adjustment images is less than 1% of the number of pre-training images used for pre-training the machine learning model.

16. The method of claim 1, wherein steps a. to d. are iterated.

17. The method of claim 1, wherein the simulation of the inspection system comprises a physical simulation of the propagation of electromagnetic waves within a photolithography mask.

18. The method of claim 1, wherein the simulation of the inspection system comprises the application of a trained machine learning model.

19. A method for defect detection in an image of a photolithography mask using a pre-trained machine learning model, the method comprising:
a. acquiring adjustment images of one or more photolithography masks using an inspection system, wherein the inspection system is configured for acquiring images of photolithography masks;
b. adjusting at least one parameter of a simulation of the inspection system using the adjustment images;
c. generating training images of one or more photolithography masks using the adjusted simulation of the inspection system;
d. re-training the machine learning model for defect detection using the generated training images; and
e. applying the re-trained machine learning model for defect detection to an image of a photolithography mask acquired by the inspection system.

20. An inspection system for detecting defects in an image of a photolithography mask comprising:
a. an image acquisition unit configured to acquire images of photolithography masks; and
b. a data analysis device comprising at least one memory and at least one processor configured to perform the steps of a method for detecting defects in an image of a photolithography mask according to claim 19.
